(19) United States
(12) Patent Application Publication
(10) Pub. No.: US 2007/0013444 A1
(43) Pub. Date: Jan. 18, 2007

(54) Parallel path pre-distorted amplifier

(76) Inventors: Ronald L. Porco, Fort Worth, TX (US); Dale R. Anderson, Colleyville, TX (US); Gary D. Burgin, Flower Mound, TX (US)

Correspondence Address: MOTOROLA, INC., 1303 EAST ALGONQUIN ROAD, IL01/3RD, SCHAUMBURG, IL, 60196, US

(21) Appl. No.: 11/179,447

(22) Filed: Jul. 12, 2005

(51) Int. Cl. H03F 1/26

(52) U.S. Cl. 330/149

(57) ABSTRACT

A power amplifier (112) has a first non-linear power amplifier (202) for generating a first amplified signal (203) and a first pre-distortion signal (205) from the carrier signal. The first amplified signal has an amplified carrier component with non-linear distortions, while the first pre-distortion signal has an in-phase carrier component with out-of-phase non-linear distortions. A second non-linear power amplifier (206) having non-linear characteristics similar to a portion of the first non-linear power amplifier is used for generating a second pre-distortion signal (207) from the pre-distortion signal. The second pre-distortion signal has an amplified carrier component with out-of-phase non-linear distortions similar but out of phase with the non-linear distortions of the first amplified signal. A first combining point (210) is used for combining the first amplified signal and the second pre-distortion signal, thereby generating a transmission signal (113) having an amplified carrier component with diminished non-linear distortions.

### FIELD OF THE INVENTION

This invention relates generally to power amplifiers, and more particularly to a parallel path pre-distorted amplifier.

### BACKGROUND OF THE INVENTION

Complex modulation schemes and systems used in today's telecommunication infrastructure require a specified amount of spectral performance from a base station. In order to meet these spectral requirements numerous schemes are used to linearize the performance of power amplifiers within the base stations. Unfortunately, known schemes (using, for example, feedforward amplifiers) fail to provide significant correction for large bandwidths at a reasonable cost and efficiency.

### SUMMARY OF THE INVENTION

Embodiments in accordance with the invention provide a parallel path pre-distorted amplifier that can offer a simple, low-cost embodiments with good efficiency and high bandwidth of operation.

In a first embodiment of the present invention, a power amplifier is provided for amplifying a carrier signal. The power amplifier has a first non-linear power amplifier for generating a first amplified signal and a first pre-distortion signal from the carrier signal. The first amplified signal has an amplified carrier component with non-linear distortions, while the first pre-distortion signal has an in-phase carrier component with out-of-phase non-linear distortions. A second non-linear power amplifier having non-linear characteristics similar to a portion of the first non-linear power amplifier is used for generating a second pre-distortion signal from the first pre-distortion signal. The second pre-distortion signal has an amplified carrier component with out-of-phase non-linear distortions similar but out of phase with the non-linear distortions of the first amplified signal. A first combining point is used for combining the first amplified signal and the second pre-distortion signal, thereby generating a transmission signal having an amplified carrier component with diminished non-linear distortions.

In a second embodiment of the present invention, a base station has a receiver for receiving signals from a selective call radio (SCR), a transmitter for generating a transmission signal directed to the SCR, and a processor for controlling operations of the receiver and the transmitter. The transmitter has an up-converter for transforming a signal at a first operating frequency to a carrier signal, a power amplifier for generating the transmission signal for radiating by an antenna that directs said signal to the SCR. The power amplifier has a first non-linear power amplifier for generating a first amplified signal and a first pre-distortion signal from the carrier signal. The first amplified signal has an amplified carrier component with non-linear distortions. The first pre-distortion signal has an in-phase carrier component with out-of-phase non-linear distortions. A second non-linear power amplifier having non-linear characteristics similar to a portion of the first non-linear power amplifier is used for generating a second pre-distortion signal from the first pre-distortion signal having an amplified carrier component with out-of-phase non-linear distortions similar but out of phase with the non-linear distortions of the first amplified signal. A first combining point is used for combining the first amplified signal and the second pre-distortion signal, thereby generating the transmission signal having an amplified carrier component with diminished non-linear distortions.

### BRIEF DESCRIPTION OF THE DRAWINGS

FIG. 1 is a block diagram of a base station in accordance with an embodiment of the present invention.

FIG. 2 is a block diagram of the power amplifier of FIG. 1 in accordance with an embodiment of the present invention.

FIGS. 3-4 are block diagrams of a first non-linear power amplifier within the power amplifier of FIG. 2 in accordance with embodiments of the present invention.

FIG. 5 depicts measurements of the transmission signal generated by the embodiment of FIG. 2 compared with a transmission signal from a prior art system.

### DETAILED DESCRIPTION

While the specification concludes with claims defining the features of embodiments of the invention that are regarded as novel, it is believed that the embodiments of the invention will be better understood from a consideration of the following description in conjunction with the figures, in which like reference numerals are carried forward.

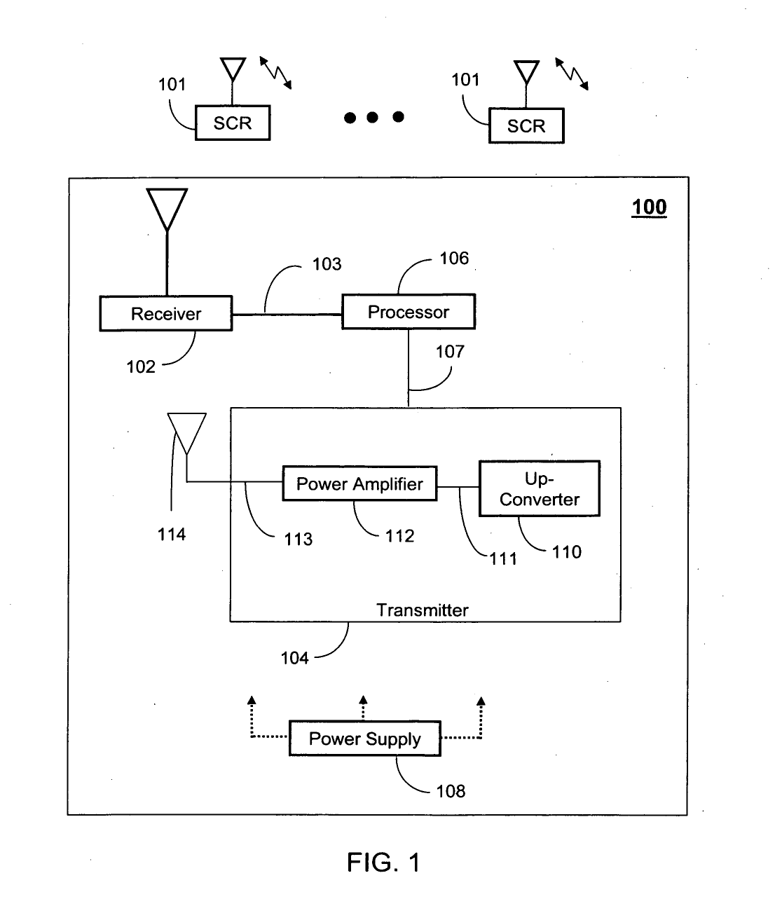

FIG. 1 is a block diagram of a base station 100 in accordance with an embodiment of the present invention. The base station 100 comprises a conventional receiver 102 for supplying intercepted signals 103 from a selective call radio (SCR) 101, a transmitter 104 for generating a transmission signal 113 directed to the SCR 101 as a radiated signal, and a conventional processor 106 for controlling operations of the receiver 102 and the transmitter 104.

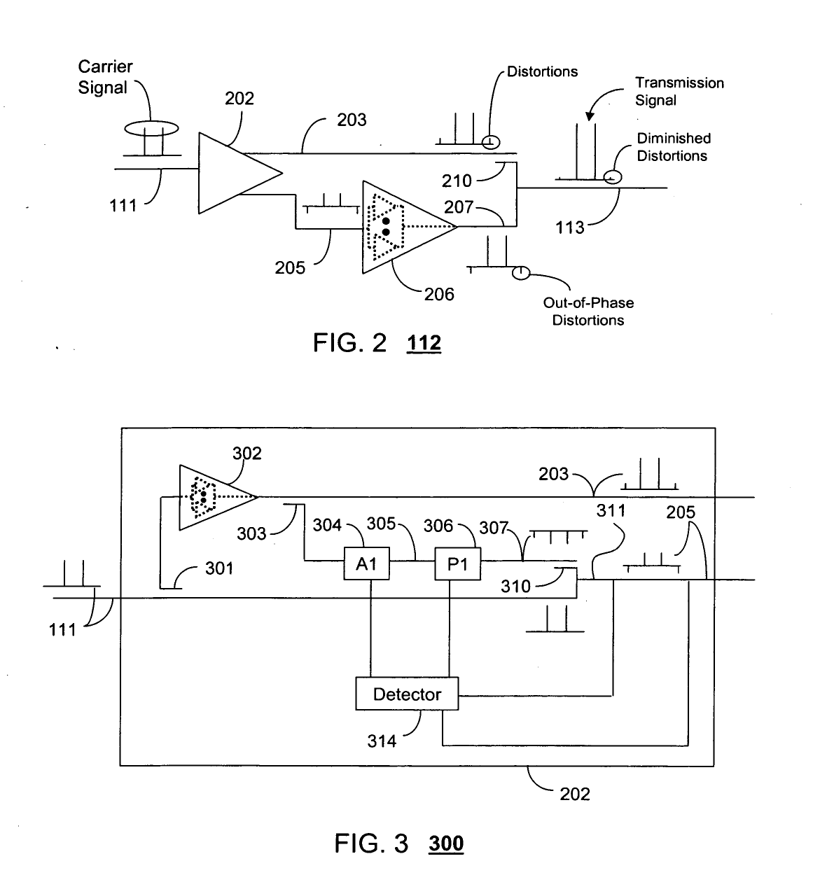

The transmitter 104 comprises a conventional up-converter 110 for transforming a signal 107 at a first operating frequency to a carrier signal 111. Signal 107 can be a baseband signal generated by the processor 106 having an embedded message intended for processing by a user of the SCR 101. Utilizing conventional technology, the up-converter 110 transforms the operating frequency of the baseband signal 107 to a carrier signal 111 operating at a carrier frequency such as, for example, 880 MHz (a typical cellular carrier band). A spectral representation of the carrier signal 111 is shown by way of example in FIGS. 2-4.

The transmitter further comprises a power amplifier 112 that transforms the carrier signal 111 to the transmission signal 113, which in turn is radiated by a conventional antenna 114 for interception by an SCR 101. A spectral representation of the transmission signal 113 is shown in FIG. 2.

The foregoing components of the base station 100 can be powered by a conventional power supply 108 such as provided by a power utility company.

FIG. 2 is a block diagram of the power amplifier 112 of FIG. 1 in accordance with an embodiment of the present invention. The power amplifier 112 comprises first and second non-linear power amplifiers 202 and 206 (herein referred to as amplifiers 202 and 206) the outputs of which are combined at a first combining point 210. Amplifier 202 generates a first amplified signal 203 and a first pre-distortion signal 205 from the carrier signal 111. The first amplified signal 203 has an amplified carrier component with non-linear distortions as shown by the spectral representation depicted in FIG. 2. The first pre-distortion signal 205, on the other hand, has an in-phase carrier component with out-of-phase non-linear distortions also depicted in FIG. 2 spectrally.

Amplifiers 202 and 206 can comprise any conventional amplification structure and associated technology such as, for example, a plurality of parallel non-linear power amplifiers (shown within the block diagram 206 as dashed lines) utilizing technology such as LDMOS (Laterally-Diffused Metal Oxide Semiconductor). Amplifier 206 has non-linear characteristics similar to a portion of amplifier 202 (see amplifiers 302 and 402) and is used for generating a second pre-distortion signal 207 from the first pre-distortion signal 205. The second pre-distortion signal 207 has an amplified carrier component with out-of-phase non-linear distortions similar but out of phase with the non-linear distortions of the first amplified signal 203. The non-linear distortions in the second pre-distortion signal 207 result from the amplified out-of-phase non-linear distortions of the first pre-distortion signal 205 combined with non-linear distortions created by amplifier 206 in the amplification process.

Combining point 210 combines the first amplified signal 203 and the second pre-distortion signal 207, thereby generating the transmission signal 113, which has an amplified carrier component with substantially diminished non-linear distortions. The non-linear distortions are substantially diminished as a result of the first amplified signal 203 and the second pre-distortion signal 207 having out of phase distortions with similar amplitude, which cancel when combined.

For the discussions that follow, amplifier 202 is assumed to use an amplifier structure and technology similar to that of amplifier 206. It will be appreciated by one of ordinary skill in the art, however, that any technology and/or structure capable of generating desired characteristics in the transmission signal 113 can be utilized for amplifiers 202 and 206 without departing from the scope and spirit of the claims herein.

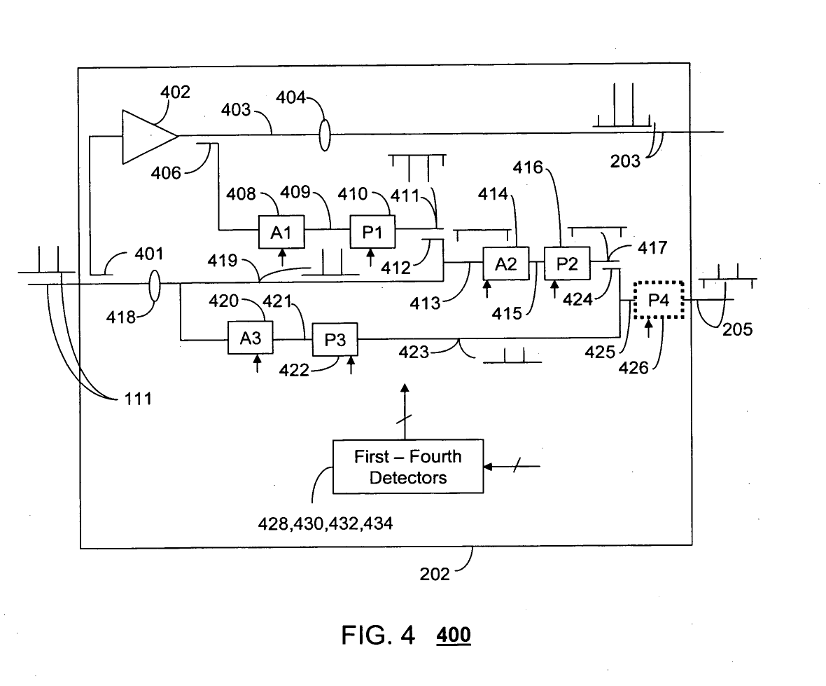

FIGS. 3-4 are block diagrams of alternate embodiments 300-400 of amplifier 202 of FIG. 2 in accordance with the present invention. According to embodiment 300 of FIG. 3, amplifier 202 includes a conventional non-linear power amplifier 302 (hereinafter referred to as amplifier 302). Amplifier 302 can include a plurality of non-linear power amplifiers similar, if not the same as those utilized by amplifier 206. Accordingly, any signal amplified by amplifier 302 will incur non-linear distortions similar to those created by amplifier 206. Amplifier 302 can be coupled to the carrier signal 111 by way of a conventional splitting point 301. Amplifier 202 further includes a conventional first attenuator 304 coupled to the amplifier 302 with a conventional combining point 303 for generating a first attenuated signal 305 having an attenuated carrier component with attenuated non-linear distortions. A conventional first phase shifter 306 coupled to the first attenuator 304 generates a first phase-shifted signal 307 having an out-of-phase carrier component with out-of-phase non-linear distortions (see spectral illustration of signal 307).

Signal 307 is combined with the carrier signal 111 utilizing a conventional second combining point 310. The resulting signal 311 has an in-phase carrier component with out-of-phase non-linear distortions as spectrally depicted in FIG. 3. The spectral result of signal 311 is accomplished by attenuating the amplitude of the out-of-phase carrier and distortion components of signal 307 (by way of the first attenuator 304) such that when they are combined with the carrier signal 111 (having a higher amplitude than the carrier portion of signal 307) an in-phase carrier component is created with out of phase distortions.

The first attenuator 304 and first phase shifter 306 are adjusted so that the ratio of amplitude between the in-phase carrier component (signal) and the out-of-phase distortions (noise) in the first pre-distorted signal 205 produces a spectral effect in the second pre-distortion signal 207 as discussed earlier with respect to FIG. 2. This ratio is chosen carefully so that amplifiers 206 and 202 generate the first amplified signal 203 and the second pre-distortion signal 207, which after combined as shown in FIG. 2 form a transmission signal 113 with minimal or no non-linear distortions.

In a supplemental embodiment, a conventional detector 314 capable of monitoring phase and amplitude can be coupled to the second combining point 310 for controlling gain and phase of the first attenuator 304 and the first phase shifter 306 so as to produce desired characteristics in the first pre-distortion signal 205 as discussed above. It will be appreciated by an artisan with ordinary skill in the art that alternatively the first attenuator 304, the first phase shifter 306 can utilize conventional non-adjustable technologies with predetermined settings to accomplish the desired characteristics in the first pre-distortion signal 205.

FIG. 4 depicts an alternate embodiment 400 of amplifier 202 in accordance with the present invention. The amplifier 202 includes a conventional non-linear power amplifier 402 (herein referred to as amplifier 402) coupled to the carrier signal 111 by way of a conventional first splitting point 401 (which can have attenuation characteristics) for generating an intermediate amplified signal 403 from the carrier signal 111 having a carrier component and non-linear distortions. Said signal 403 is fed to a conventional delay element 404 for generating the first amplified signal 203. The first amplified signal 203 has similar spectral characteristics as described earlier in embodiment 300 with the exception of a delay factor, which is utilized for balancing delays incurred by circuitry generating the first and second pre-distortion signals 205 and 207.

A conventional first attenuator 408 is coupled to the amplifier 402 by conventional means 406 for generating a first attenuated signal 409 having an attenuated carrier component with attenuated non-linear distortions. A first phase shifter 410 coupled thereto generates a first phase-shifted signal 411 having an out-of-phase carrier component with out-of-phase non-linear distortions similar to what was described in embodiment 300.

A second combining point 412 combines a delayed version of the carrier signal 111 generated by a conventional second delay element 418 with the first phase-shifted signal 411, thereby generating a signal 413 having a substantially canceled carrier component and out-of-phase non-linear distortions. A second attenuator 414 generates a second attenuated signal 415. A conventional second phase shifter 416 is coupled to the second attenuator 414 for generating a second phase-shifted distortion signal 417.

The amplifier 202 further includes a conventional third attenuator 420 coupled to the second delay element 418 for generating an attenuated carrier signal 421 which is then processed by a conventional third phase shifter 422 for generating a third phase-shifted carrier signal 423. A conventional third combining point 424 is used for generating the first pre-distortion signal 205 by combining the second phase-shifted distortion signal 417 and the phase-shifted carrier signal 423. In a supplemental embodiment, the third combining point 424 generates a third combined signal 425 which is phase adjusted by a conventional fourth phase shifter 426 thereby generating a phase-shifted version of the pre-distortion signal 425.

In yet another supplemental embodiment, conventional first through third detectors 428, 430 and 432 capable of monitoring phase and amplitude can be coupled to the second and third combining points 412, 424 for controlling amplitude and phase of the first through third attenuators 408, 414, 420 and the first through third phase shifters 410, 416, 422 to produce desired characteristics in the first pre-distortion signal 205. In the embodiment that includes the fourth phase shifter 426, a fourth conventional detector 434 can be coupled to the first combining point 210 to monitor a maximum power level and thereby adjust phase in the fourth phase shifter 426 in order to produce desired characteristics in the first pre-distortion signal 205. Alternatively, the fourth conventional detector 434 can be coupled to the first amplified signal 203 or the second pre-distortion signal 207 to monitor a minimum reflective power level (at, for example an isolator's termination port), and similarly adjust phase in the fourth phase shifter 426 to produce desired characteristics in the first or second pre-distortion signals 205 or 207.

In the embodiment of FIG. 4, the ratio of the amplitude of the in-phase carrier component and out-of-phase non-linear distortions of the first pre-distortion signal 205 are controlled so as to produce a desired spectral effect in the second pre-distortion signal 207. This is accomplished by operating amplifier 206 in the same (or nearly the same) non-linear region as amplifiers 302 or 402 of said embodiments.

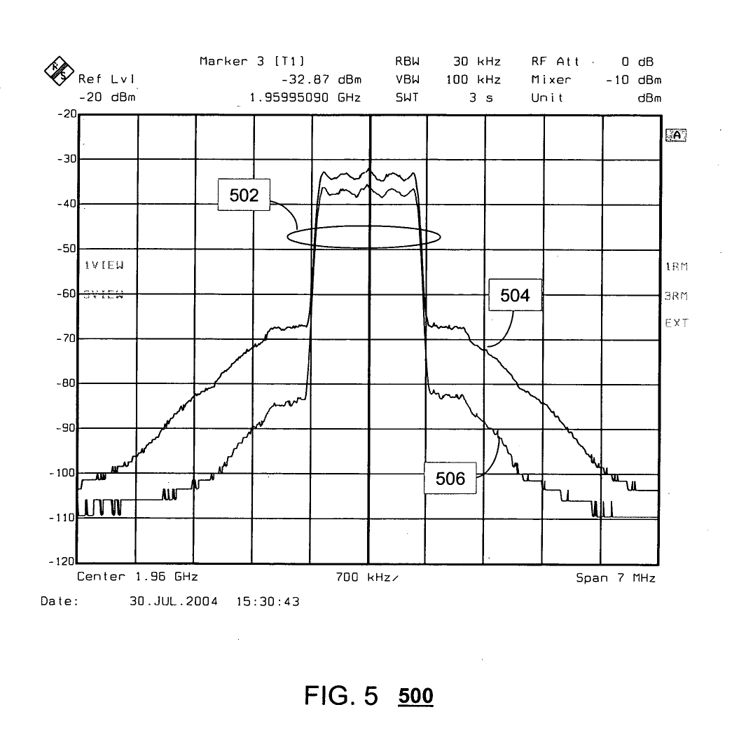

FIG. 5 depicts measurements of the transmission signal 115 generated by the embodiment of FIG. 2 compared with a transmission signal from a prior art system. The spectral results show that the carrier signal 502 (single carrier in this example) is similar in both systems. However, the non-linear distortions 504 from an uncorrected system are substantially greater than the non-linear distortions 506 of the embodiment of FIG. 2.

It should be evident to an artisan with skill in the art that portions of embodiments of the present invention can be embedded in a computer program product, which comprises features enabling the implementation stated above. A computer program in the present context means any expression, in any language, code or notation, of a set of instructions intended to cause a system having an information processing capability to perform a particular function either directly or after either or both of the following: a) conversion to another language, code or notation; b) reproduction in a different material form.

It should be also evident that embodiments of the present invention may be used for many applications. Thus, although the description is made for particular arrangements, the intent and concept herein is suitable and applicable to other arrangements and applications not necessarily described herein. For example, it should be evident to an artisan with ordinary skill in the art that the power amplifier 112 described above can be used in other applications not described. Accordingly, aspects of embodiments 300 and 400 can be combined and/or modified without departing from the scope and spirit of the claimed invention so long as the spectral characteristics of the second pre-distortion signal 207 have pre-distorted non-linear components that can diminish the distortions of the first amplified signal 203 in whole or in part when both signals are combined.

Additionally, components of the amplifier 112 can be modified without departing from the claimed invention. For example, the delay elements 404 and 418 of FIG. 4 can be removed while remaining operable within the scope of the embodiments. Similarly, fewer or greater attenuators and phase shifters can be utilized in embodiments 300 and 400, again without departing from the operational scope of the claims. Clearly, modifications to the disclosed embodiments can be implemented without departing from the spirit and scope of the appended claims.

Accordingly, the described embodiments ought to be construed to be merely illustrative of some of the more prominent features and applications of the invention. It should also be understood that the claims are intended to cover the structures described herein as performing the recited function and not only structural equivalents. Therefore, equivalent structures that read on the description should also be construed to be inclusive of the scope of the invention as defined in the following claims. Thus, reference should be made to the following claims, rather than to the foregoing specification, as indicating the scope of the invention.

What is claimed is:

1. A power amplifier for amplifying a carrier signal, comprising:
a first non-linear power amplifier for generating a first amplified signal and a first pre-distortion signal from the carrier signal, the first amplified signal has an amplified carrier component with non-linear distortions, and the first pre-distortion signal has an in-phase carrier component with out-of-phase non-linear distortions;
a second non-linear power amplifier having non-linear characteristics similar to a portion of the first non-linear power amplifier for generating a second pre-distortion signal from the first pre-distortion signal having an amplified carrier component with out-of-phase non-linear distortions similar but out of phase with the non-linear distortions of the first amplified signal; and
a first combining point for combining the first amplified signal and the second pre-distortion signal, thereby generating a transmission signal having an amplified carrier component with diminished non-linear distortions.

2. The power amplifier of claim 1, wherein the first non-linear power amplifier comprises:
a non-linear power amplifier coupled to the carrier signal for generating the first amplified signal;
a first attenuator coupled to the non-linear power amplifier for generating a first attenuated signal having an attenuated carrier component with attenuated non-linear distortions;
a first phase shifter coupled to the first attenuator for generating a first phase-shifted signal having an out-of-phase carrier component with out-of-phase non-linear distortions; and
a second combining point for generating the first pre-distortion signal by combining the first phase-shifted signal and the carrier signal.

3. The power amplifier of claim 2, further comprising a detector coupled to the second combining point for controlling gain and phase of the first attenuator and the first phase shifter to produce desired characteristics in the pre-distortion signal.

4. The power amplifier of claim 1, wherein the first non-linear power amplifier comprises:
a non-linear power amplifier for generating an intermediate amplified signal from the carrier signal having a carrier component and non-linear distortions;
a first delay element coupled to the non-linear power amplifier for generating the first amplified signal from the intermediate amplified signal;
a first attenuator coupled to the non-linear power amplifier for generating a first attenuated signal having an attenuated carrier component with attenuated non-linear distortions;
a first phase shifter coupled to the first attenuator for generating a first phase-shifted signal having an out-of-phase carrier component with out-of-phase non-linear distortions;
a second delay element for generating from the carrier signal a delayed carrier signal;
a second combining point for generating a combined signal from the first phase-shifted signal and the delayed carrier signal having out-of-phase non-linear distortions and a substantially canceled carrier component;
a second attenuator coupled to the second combining point for generating an attenuated distortion signal;
a second phase shifter coupled to the second attenuator for generating in combination a phase-shifted distortion signal;
a third attenuator coupled to the second delay element;
a third phase shifter coupled to the third attenuator for generating in combination a phase-shifted carrier signal; and
a third combining point for generating the first pre-distortion signal by combining the phase-shifted distortion signal and the phase-shifted carrier signal.

5. The power amplifier of claim 4, further comprising first through third detectors coupled to the second and third combining points for controlling amplitude and phase of the first through third attenuators and the first through third phase shifters to produce desired characteristics in the pre-distortion signal.

6. The power amplifier of claim 1, wherein the first non-linear power amplifier comprises:
a non-linear power amplifier for generating the first amplified signal from the carrier signal;
a first attenuator coupled to the non-linear power amplifier for generating a first attenuated signal having an attenuated carrier component with attenuated non-linear distortions;
a first phase shifter coupled to the first attenuator for generating a first phase-shifted signal having an out-of-phase carrier component with out-of-phase non-linear distortions;
a second combining point for generating a combined signal from the first phase-shifted signal and the delayed carrier signal having out-of-phase non-linear distortions and a substantially canceled carrier component;
a second attenuator coupled to the second combining point for generating an attenuated distortion signal;
a second phase shifter coupled to the second attenuator for generating in combination a phase-shifted distortion signal;
a third attenuator for generating an attenuated carrier signal from the carrier signal;
a third phase shifter coupled to the third attenuator for generating a phase-shifted carrier signal from the attenuated carrier signal; and
a third combining point for generating the first pre-distortion signal by combining the phase-shifted distortion signal and the phase-shifted carrier signal.

7. The power amplifier of claim 6, further comprising first through third detectors coupled to the second and third combining points for controlling amplitude and phase of the first through third attenuators and the first through third phase shifters to produce desired characteristics in the pre-distortion signal.

8. The power amplifier of claim 1, wherein the first non-linear power amplifier comprises:
a non-linear power amplifier for generating from the carrier signal an intermediate amplified signal having a carrier component and non-linear distortions;
a first delay element coupled to the non-linear power amplifier for delaying the intermediate amplified signal, thereby generating the first amplified signal;
a first attenuator coupled to the non-linear power amplifier for generating a first attenuated signal having an attenuated carrier component with attenuated non-linear distortions;
a first phase shifter coupled to the first attenuator for generating a first phase-shifted signal having an out-of-phase carrier component with out-of-phase non-linear distortions;
a second delay element for generating from the carrier signal a delayed carrier signal;
a second combining point for generating a combined signal from the first phase-shifted signal and the delayed carrier signal having out-of-phase non-linear distortions and a substantially canceled carrier component;
a second attenuator coupled to the second combining point for generating an attenuated distortion signal;
a second phase shifter coupled to the second attenuator for generating in combination a phase-shifted distortion signal;
a third attenuator coupled to the second delay element;
a third phase shifter coupled to the third attenuator for generating a phase-shifted carrier signal;
a third combining point for combining the phase-shifted distortion signal and the phase-shifted carrier signal; and
a fourth phase shifter coupled to the third combining point for phase-shifting the third combined signal and thereby generating the pre-distortion signal.

9. The power amplifier of claim 8, further comprising first through third detectors coupled to the second and third combining points for controlling gain and phase of the first through third attenuators and the first through third phase shifters, and a fourth detector coupled to at least one among the first combining point, the first amplified signal, and the second pre-distortion signal for controlling phase of the fourth phase shifter to produce desired characteristics in at least one among the first pre-distortion signal and the second pre-distortion signal.

10. The power amplifier of claim 1, wherein the first and second non-linear power amplifiers each comprise a plurality of parallel non-linear power amplifiers.

11. A base station, comprising:
a receiver for receiving signals from a selective call radio (SCR);
a transmitter for generating a transmission signal directed to the SCR; and
a processor for controlling operations of the receiver and the transmitter, wherein the transmitter comprises:
an up-converter for transforming a signal at a first operating frequency to a carrier signal; and
a power amplifier for generating the transmission signal for radiating by an antenna that directs said signal to the SCR, wherein the power amplifier comprises:
a first non-linear power amplifier for generating a first amplified signal and a first pre-distortion signal from the carrier signal, the first amplified signal has an amplified carrier component with non-linear distortions, and the first pre-distortion signal has an in-phase carrier component with out-of-phase non-linear distortions;
a second non-linear power amplifier having non-linear characteristics similar to a portion of the first non-linear power amplifier for generating a second pre-distortion signal from the first pre-distortion signal having an amplified carrier component with out-of-phase non-linear distortions similar but out of phase with the non-linear distortions of the first amplified signal; and
a first combining point for combining the first amplified signal and the second pre-distortion signal, thereby generating a transmission signal having an amplified carrier component with diminished non-linear distortions.

12. The base station of claim 11, wherein the first non-linear power amplifier comprises:
a non-linear power amplifier coupled to the carrier signal for generating the first amplified signal;
a first attenuator coupled to the non-linear power amplifier for generating a first attenuated signal having an attenuated carrier component with attenuated non-linear distortions;
a first phase shifter coupled to the first attenuator for generating a first phase-shifted signal having an out-of-phase carrier component with out-of-phase non-linear distortions; and
a second combining point for generating the first pre-distortion signal by combining the first phase-shifted signal and the carrier signal.

13. The base station of claim 12, further comprising a detector coupled to the second combining point for controlling amplitude and phase of the first attenuator and the first phase shifter to produce desired characteristics in the pre-distortion signal.

14. The base station of claim 11, wherein the first non-linear power amplifier comprises:
a non-linear power amplifier for generating an intermediate amplified signal from the carrier signal having a carrier component and non-linear distortions;
a first delay element coupled to the non-linear power amplifier for generating the first amplified signal from the intermediate amplified signal;
a first attenuator coupled to the non-linear power amplifier for generating a first attenuated signal having an attenuated carrier component with attenuated non-linear distortions;
a first phase shifter coupled to the first attenuator for generating a first phase-shifted signal having an out-of-phase carrier component with out-of-phase non-linear distortions;
a second delay element for generating from the carrier signal a delayed carrier signal;
a second combining point for generating a combined signal from the first phase-shifted signal and the delayed carrier signal having out-of-phase non-linear distortions and a substantially canceled carrier component;
a second attenuator coupled to the second combining point for generating an attenuated distortion signal;
a second phase shifter coupled to the second attenuator for generating in combination a phase-shifted distortion signal;
a third attenuator coupled to the second delay element;
a third phase shifter coupled to the third attenuator for generating in combination a phase-shifted carrier signal; and
a third combining point for generating the first pre-distortion signal by combining the phase-shifted distortion signal and the phase-shifted carrier signal.

15. The base station of claim 14, further comprising first through third detectors coupled to the second and third combining points for controlling amplitude and phase of the first through third attenuators and the first through third phase shifters to produce desired characteristics in the pre-distortion signal.

16. The base station of claim 11, wherein the first non-linear power amplifier comprises:
a non-linear power amplifier for generating the first amplified signal from the carrier signal;
a first attenuator coupled to the non-linear power amplifier for generating a first attenuated signal having an attenuated carrier component with attenuated non-linear distortions;
a first phase shifter coupled to the first attenuator for generating a first phase-shifted signal having an out-of-phase carrier component with out-of-phase non-linear distortions;
a second combining point for generating a combined signal from the first phase-shifted signal and the delayed carrier signal having out-of-phase non-linear distortions and a substantially canceled carrier component;
a second attenuator coupled to the second combining point for generating an attenuated distortion signal;
a second phase shifter coupled to the second attenuator for generating in combination a phase-shifted distortion signal;
a third attenuator for generating an attenuated carrier signal from the carrier signal;
a third phase shifter coupled to the third attenuator for generating a phase-shifted carrier signal from the attenuated carrier signal; and
a third combining point for generating the first pre-distortion signal by combining the phase-shifted distortion signal and the phase-shifted carrier signal.

17. The base station of claim 16, further comprising first through third detectors coupled to the second and third combining points for controlling gain and phase of the first through third attenuators and the first through third phase shifters to produce desired characteristics in the pre-distortion signal.

18. The base station of claim 11, wherein the first non-linear power amplifier comprises:
a non-linear power amplifier for generating from the carrier signal an intermediate amplified signal having a carrier component and non-linear distortions;
a first delay element coupled to the non-linear power amplifier for delaying the intermediate amplified signal, thereby generating the first amplified signal;
a first attenuator coupled to the non-linear power amplifier for generating a first attenuated signal having an attenuated carrier component with attenuated non-linear distortions;
a first phase shifter coupled to the first attenuator for generating a first phase-shifted signal having an out-of-phase carrier component with out-of-phase non-linear distortions;
a second delay element for generating from the carrier signal a delayed carrier signal;
a second combining point for generating a combined signal from the first phase-shifted signal and the delayed carrier signal having out-of-phase non-linear distortions and a substantially canceled carrier component;
a second attenuator coupled to the second combining point for generating an attenuated distortion signal;
a second phase shifter coupled to the second attenuator for generating in combination a phase-shifted distortion signal;
a third attenuator coupled to the second delay element;
a third phase shifter coupled to the third attenuator for generating a phase-shifted carrier signal;
a third combining point for combining the phase-shifted distortion signal and the phase-shifted carrier signal; and
a fourth phase shifter coupled to the third combining point for phase-shifting the third combined signal and thereby generating the pre-distortion signal.

19. The base station of claim 18, further comprising first through third detectors coupled to the second and third combining points for controlling gain and phase of the first through third attenuators and the first through third phase shifters, and a fourth detector coupled to at least one among the first combining point, the first amplified signal, and the second pre-distortion signal for controlling phase of the fourth phase shifter to produce desired characteristics in at least one among the first pre-distortion signal and the second pre-distortion signal.

20. The base station of claim 11, wherein the first and second non-linear power amplifiers each comprise a plurality of parallel non-linear power amplifiers.
